(19) United States
(12) Patent Application Publication
(10) Pub. No.: US 2026/0047119 A1
(43) Pub. Date: Feb. 12, 2026

(54) METHODS FOR FORMING SEMICONDUCTOR DEVICE HAVING NANOSHEET TRANSISTOR

(71) Applicant: TAIWAN SEMICONDUCTOR MANUFACTURING COMPANY, LTD., Hsinchu (TW)

(72) Inventors: Kuei-Yu KAO, Hsinchu (TW); Chiung-Yu CHO, Hsinchu (TW)

(21) Appl. No.: 18/795,247

(22) Filed: Aug. 6, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017

(57) ABSTRACT

Various embodiments of the present disclosure provide a method for forming a semiconductor device structure. The method includes forming a trench between two adjacent fin structures each comprising a plurality of first semiconductor layers and a plurality of second semiconductor layers alternatingly stacked, removing the second semiconductor layers in each fin structure to form first cavities, filling the first cavities with a sacrificial dielectric layer, removing edge portions of each sacrificial dielectric layer to form second cavities, filling the second cavities with a dielectric spacer, forming epitaxial source/drain features in the trench, removing the sacrificial dielectric layers, and surrounding a portion of each first semiconductor layer with a gate electrode layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, as dimensions of integrated circuits continue to scale to smaller sub-micron sizes in advanced node applications, it becomes an increasing challenge to reduce channel resistance while maintaining desired electric current for the device. Therefore, improved structures and methods for manufacturing the same are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are perspective views of various stages of manufacturing a semiconductor device structure in accordance with some embodiments.

FIGS. 6, 7, 8, 9, 10, 11, 12, 13, 14, 15, 16, 17, 18, 19, 20, 21, 22, 23, 24, 25, 26, and 27 are cross-sectional side views of various stages of manufacturing the semiconductor device structure taken along cross-section A-A of FIG. 5, in accordance with some embodiments.

FIG. 16-1 is a cross-sectional side view of the semiconductor device structure taken along cross-section A-A of FIG. 5, in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

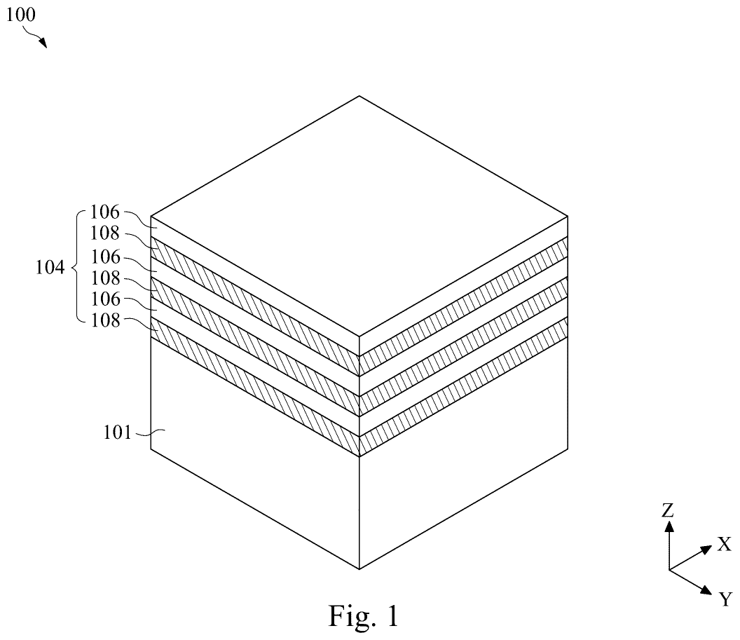

FIGS. 1 to 27 show non-limiting processes for manufacturing a semiconductor device structure 100 according to embodiments of the present disclosure. It is understood that additional operations can be provided before, during, and after processes shown by FIGS. 1 to 27, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100 in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 may include various regions that have been doped with impurities (e.g., dopants having p-type or n-type conductivity). Depending on circuit design, the dopants may be, for example phosphorus for n-well and/or an n-type field effect transistors (NFET) and boron for p-well and/or a p-type field effect transistors (PFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

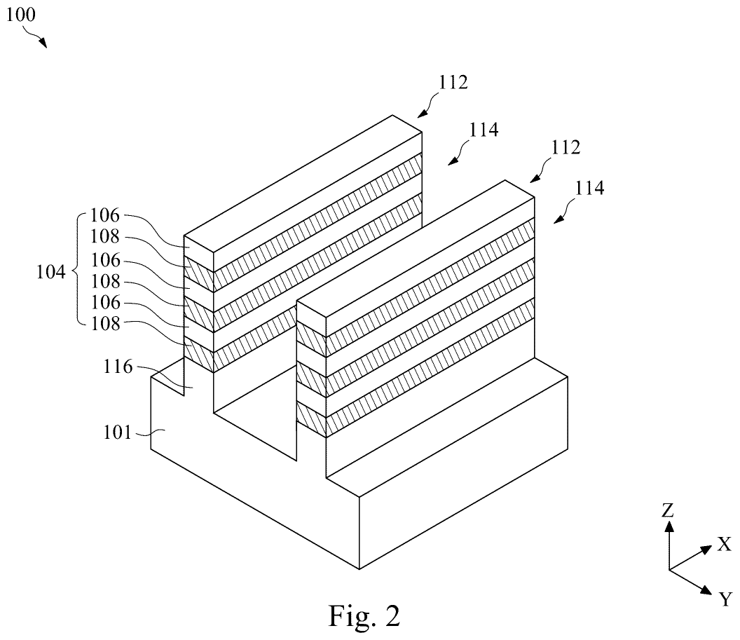

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

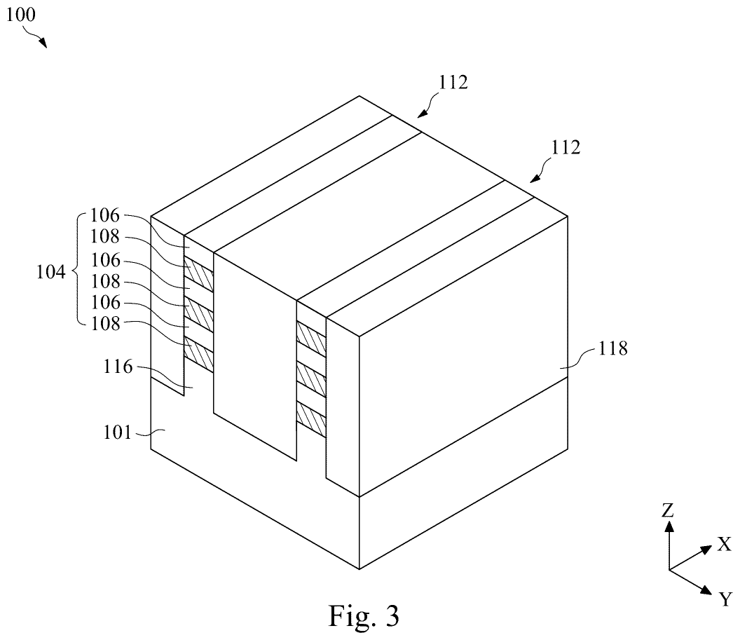

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

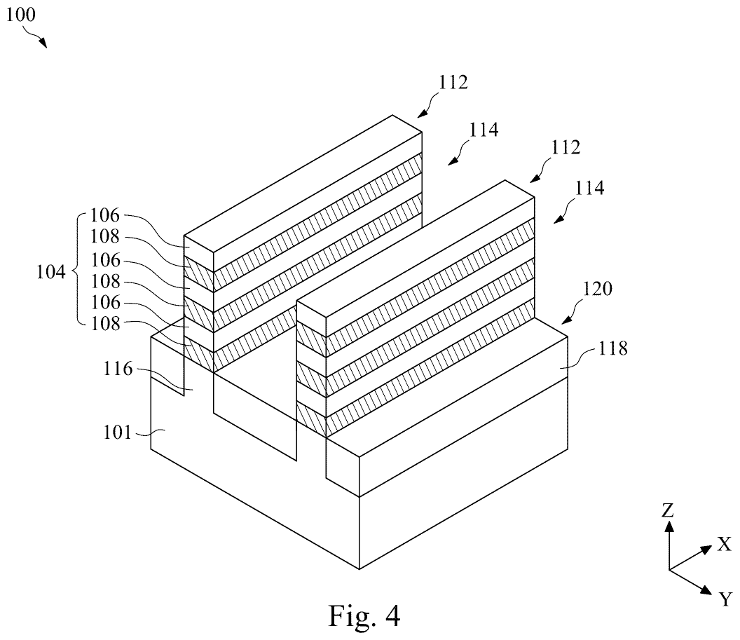

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101.

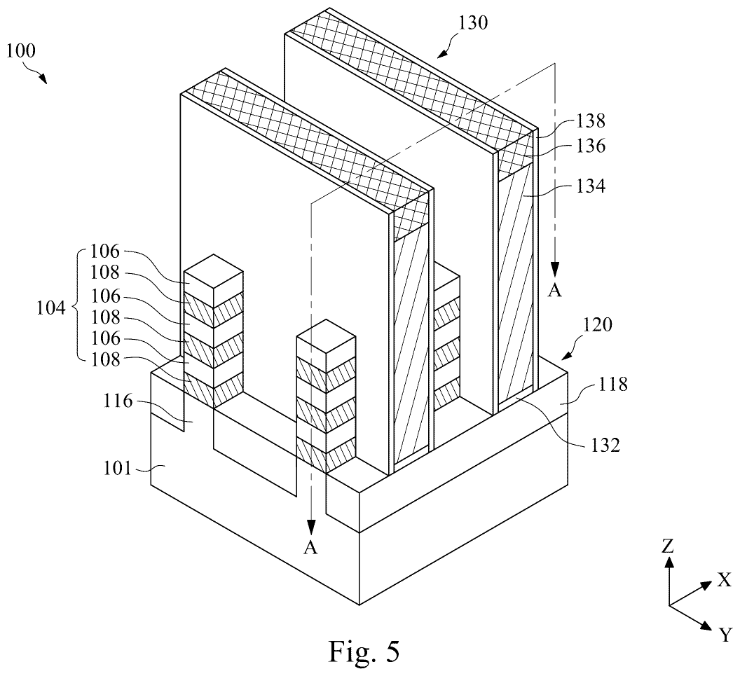

In FIG. 5, one or more sacrificial gate structures 130 (only two are shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While two sacrificial gate structures 130 are shown, three or more sacrificial gate structures 130 may be arranged along the X direction in some embodiments.

The sacrificial gate dielectric layer 132 may include one or more layers of dielectric material, such as silicon oxide (SiOₓ) or a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof. In some embodiments, the gate spacer 138 may be a dual-layer including a first dielectric layer 138a (e.g., SiO₂) and a second dielectric layer 138b (e.g., SiN).

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various S/D regions may be connected together and implemented as multiple functional transistors. It should be understood that the source region and the drain region can be interchangeably used since the epitaxial features to be formed in these regions are substantially the same. Source/drain region(s) may refer to a source or a drain, individually or collectively dependent upon the context.

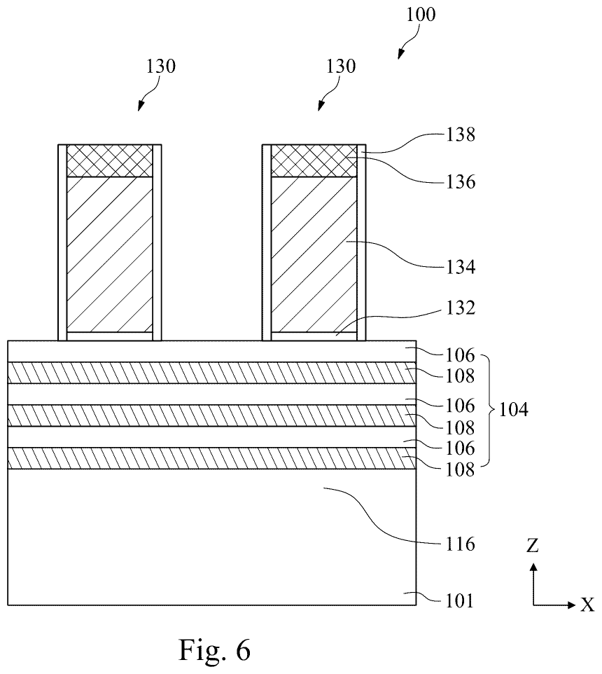

FIGS. 6-27 are cross-sectional side views of various stages of manufacturing the semiconductor device structure 100 taken along cross-section A-A of FIG. 5, in accordance with some embodiments.

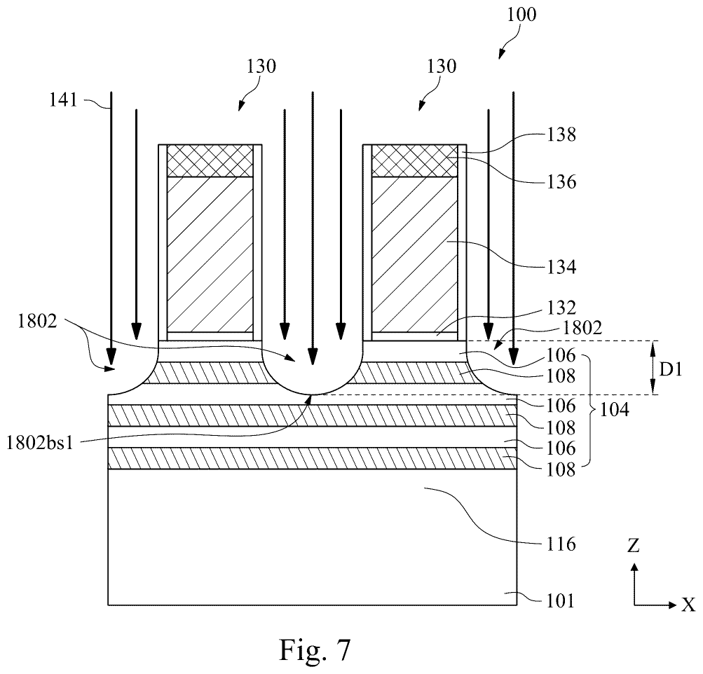

FIGS. 7-16 illustrate various stages of a cyclic process for removal of the fin structures 112 for forming trenches in the S/D regions (e.g., regions on opposite sides of the sacrificial gate structure 130). Particularly, the trenches (and thus subsequent epitaxial S/D features) are formed with a substantially straight vertical sidewall profile. The cyclic process may include a plurality of process cycles each process cycle comprising an etch step, a passivation step, and a treatment step. The etch step in each process cycle is configured to remove a portion of the first and second semiconductor layers 106, 108. The passivation step in each process cycle is configured to protect exposed surfaces of the trenches from over-etching during subsequent etch process. The treatment step in each process cycle is configured to soften the previously formed passivation layer for easy removal at the subsequent etch step in the next process cycle. The cyclic process is performed until a desired depth of the trench is reached.

FIG. 7 shows an etch step 141 of a first process cycle in a cyclic process. The etch step 141 is performed to remove the first and second semiconductor layers 106, 108, thereby forming the trenches 1802 with a first depth. A portion of the insulating material 118 around the fin structures 112 may also be removed. The etch step 141 may be a dry etch process, such as RIE, NBE, or any suitable anisotropic etch process. In one exemplary embodiment, the etch step 141 is a plasma etch process. The etch step 141 may be performed until the topmost second semiconductor layer 108 is etched through. After the etch step 141, the trenches 1802 may have a depth D1, which is defined by a distance between a top surface of the topmost first semiconductor layer 106 and a bottom surface 1802bs1 of the trenches 1802. In some embodiments, the bottom surface 1802bs1 of the trenches 1802 is at or near an interface defined by the topmost second semiconductor layer 108 and the first semiconductor layer 106 immediately below the topmost second semiconductor layer 108.

The etch step 141 is a plasma etch process using a hydrocarbon-based etch chemistry, a bromine-based etch chemistry, a chlorine-based etch chemistry, a fluorine-based etch chemistry, or the like. Exemplary hydrocarbon-based etch chemistry may include methane (CH₄), ethane (C₂H₆), propane (C₃H₈), or the like, or a combination thereof. Exemplary bromine-based etch chemistry may include hydrogen bromide (HBr), bromine (Br₂), boron tribromide (BBr₃), or the like, or a combination thereof. Exemplary chlorine-based etch chemistry may include chlorine gas (Cl₂), chloroform (CHCl₃), carbon tetrachloride (CCl₄), boron trichloride (BCl₃), or the like, or a combination thereof. Exemplary fluorine-containing gas may include tetrafluoromethane (CF₄), hexafluoroethane (C₂F₆), octofluorocyclobutane (C₄F₈), hexafluorobutadiene (C₄F₆), sulfur hexafluoride (SF₆), nitrogen trifluoride (NF₃), difluoromethane (CH₂F₂), difluoroethane (C₂H₄F₂), trifluoromethane (CHF₃), hexafluoroethane (C₂F₆), or the like, or a combination thereof. A dilute gas, such as helium (He), nitrogen (N₂), or the like, may also be used in combination with the etch chemistries. An inert gas, such as argon (Ar), neon (Ne), krypton (Kr), or the like, may be provided with the etch chemistries to increase bombardment effect and thus, enhanced etch rates of the first and second semiconductor layers 106, 108.

In some embodiments, the plasma etch process may utilize a capacitively coupled plasma (CCP) source, an inductively coupled plasma (ICP) source, dipole antenna plasma source, a resonant antenna plasma source, an electron cyclotron resonance (ECR) plasma source, or glow discharge plasma (GDP) source driven by an RF power generator or a microwave plasma source using a tunable frequency ranging from about 2 MHz to about 2.45 GHz, such as about 13.56 MHz. The process chamber may be operated at a pressure in a range of about 5 mTorr to about 20 mTorr and a temperature of about 20 degrees Celsius to about 240 degrees Celsius. The RF power generator is operated to provide a source power between about 100 W to about 300 W. A biasing power in a range of about 100 W to about 300 W is provided to a substrate support on which the semiconductor device structure 100 is disposed to provide etch directionality. The source power and the biasing power may be controlled so that the ion acceleration energy is between about 20 eV to about 200 eV. In some cases, a pulse plasma etch may be used. In such cases, the output of the power generator may be controlled by a pulse signal having a duty cycle in a range of about 5% to 95%. Alternatively, the plasma etch process may use a bias power only (with zero source power). In some embodiments, the plasma etch process may be performed in a plasma etch chamber with in-situ ALD capability. In one exemplary embodiment, the plasma etch process uses a plasma formed from a gas mixture containing CH₄, Cl₂, HBr, CHF₃, for example.

In some embodiments, the plasma etch process may utilize a decoupled plasma process using an ICP source driven by the RF power generator. The RF power generator may use a tunable frequency ranging from about 2 MHz to about 13.56 MHZ, and the process chamber may be operated at a pressure in a range of about 1 mTorr to about 800 mTorr and a temperature of about 0 degrees Celsius to about 140 degrees Celsius for a process time of about 3 seconds to about 200 seconds. The flow of the processing gas (e.g., hydrogen-containing and nitrogen-containing gas) may be separately provided at about 200 sccm to about 5000 sccm. The RF power generator may be operated to provide power between about 50 watts to about 1000 watts, and the output of the RF power generator is controlled by a pulse signal having a duty cycle in a range of about 20% to about 80%.

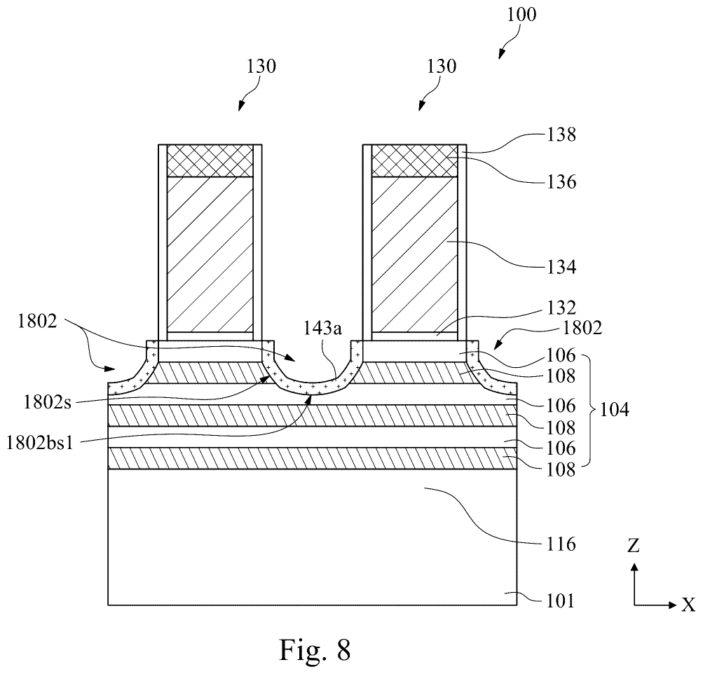

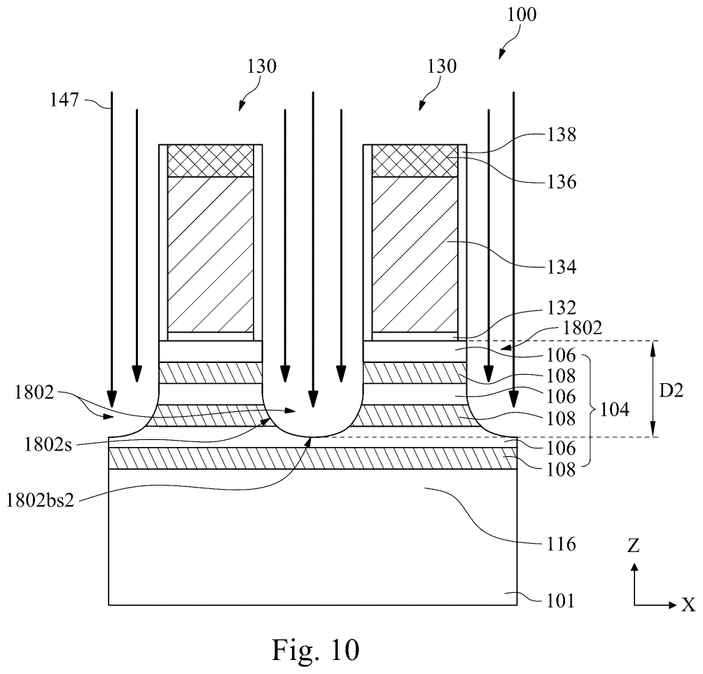

FIG. 8 shows a passivation step of the first process cycle in the cyclic process. The passivation step is performed to form a passivation layer 143a on the exposed surfaces of the trenches 1802, such as a sidewall 1802s and a bottom surface 1802bs1 of the trenches 1802. The passivation layer 143a protects the exposed surfaces of the trenches 1802 from over-etching in the lateral direction during the subsequent etch step. In some embodiments, the passivation layer 143a may be configured to lower the etching selectivity of the exposed surfaces of the trenches 1802 to the etchants used for subsequent etch process, such as the etch step 147 shown in FIG. 10. A biasing power is applied to the substrate support during the passivation step so that the majority of etch chemistries is directed towards the bottom of the trenches 1802. Therefore, while the passivation layer 143a at the sidewall 1802s and bottom surface 1802bs1 of the trenches 1802 is exposed to the etchants, the passivation layer 143a at the bottom surface 1802bs1 of the trenches 1802 is removed at a faster rate than the rate of the passivation layer 143a on the sidewall 1802s of the trenches 1802. With this approach, the impact of the etchant on the sidewall 1802s of the trenches 1802 is diminished by the passivation layer 143a, allowing the trenches 1802 to be extended vertically with a straight and symmetric sidewall profile during the subsequent etch step. In some embodiments, the passivation layer 143a may have a thickness between about 1 nm and about 3 nm.

The passivation layer 143a may be a dielectric material or an oxide-based passivation layer, such as SiO, SiON, SiN, SiO₂, or the like, or any combination thereof. In some embodiments, the passivation layer 143a may be formed by exposing the exposed surfaces of the trenches 1802 to a gas mixture comprising a silicon-containing precursor (e.g., SiCl₄), an oxygen-containing precursor (e.g., O₂), and/or a nitrogen-containing precursor (e.g., N₂). The precursors may flow concurrently or sequentially into the process chamber. In some embodiments, a hydrogen halide such as hydrogen bromide (HBr) may be flowed along with the silicon-containing precursor and the oxygen-containing precursor. In some embodiments, the passivation layer 143a is deposited by an in-situ ALD process in the same chamber as the plasma etch process used for the etch step 141. For example, an in-site ALD technique using precursors such as DIPAS (di (isopropylamino) silane) and BTBAS (bis (tertiary-butylamino) silane) in combination with Ar or O₂ plasma treatment to form a silicon-containing film. For example, the passivation layer 143a may be formed by supplying a silicon-containing source gas, such as DIPAS or BTBAS, to the process chamber, supplying a plasma of a reactive gas, such as an oxygen-containing gas or a nitrogen-containing gas, to the process chamber. The radicals from the plasma of the reactive gas oxidize or nitride substances derived from the silicon-containing source gas to form the silicon-containing film.

In some embodiments, the passivation step may utilize the same plasma source as the etch step 141. The process chamber may be operated at a pressure in a range of about 5 mTorr to about 20 mTorr. The RF power generator is operated to provide a source power between about 100 W to about 300 W. A biasing power in a range of about 10 W to about 50 W is provided to the substrate support during the passivation step. In some embodiments, the source power used during the passivation step (e.g., 200 W to about 500 W) is greater than the etch step 141 (e.g., 100 W to about 300 W), and the biasing power (e.g., 10 W to about 50 W) used during the passivation step is lower than the etch step 141 (e.g., 100 W to about 300 W). In some embodiments, the etch step 141 and the passivation step may be performed in the same process chamber with in-situ ALD capability. In one exemplary embodiment, the passivation step in the first process cycle uses a plasma formed from a gas mixture containing N₂ and/or O₂, for example.

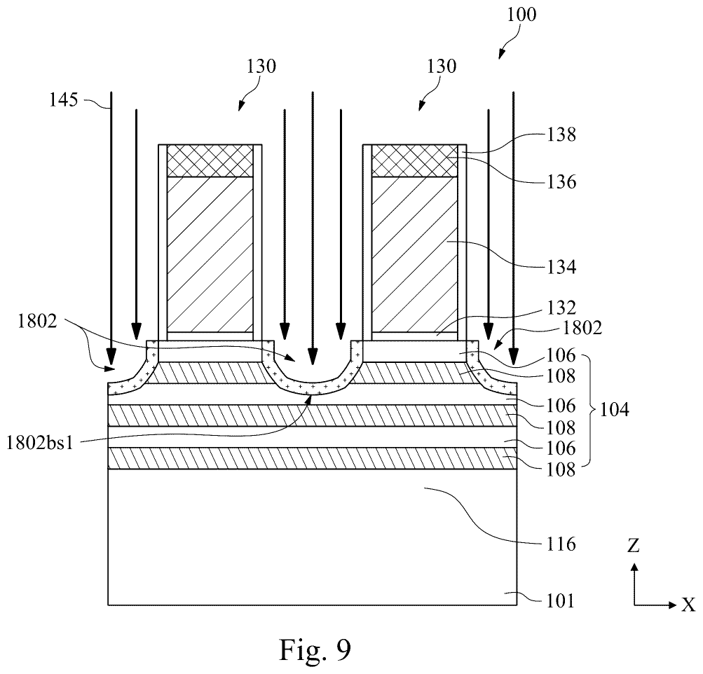

FIG. 9 shows a treatment step 145 of the first process cycle in the cyclic process. The treatment step 145 is performed to bombard and soften the passivation layer 143a. The softened passivation layer 143a allows its easy removal during the subsequent etch step at the next process cycle. The treatment step 145 may be a bombardment process using plasma formed from hydrogen gas (H₂), N₂, Ar, or the like, or any combination thereof. In some embodiments, the treatment step 145 uses neutral radical of species formed from a nitrogen-containing gas, a hydrogen-containing gas, or a combination thereof.

In some embodiments, the treatment step 145 may utilize the same plasma source as the etch step 141. The process chamber may be operated at a pressure in a range of about 50 mTorr to about 100 mTorr. A biasing power is applied to the substrate support during the treatment step 145 so that the majority of ions and/or radicals are directed towards the bottom of the trenches 1802 for greater directionality. Higher directionality can also be achieved by lowering frequency for biasing power. In some embodiments, the source power (e.g., 50 W to about 100 W) used during the treatment step 145 is less than that of the etch step 141 (e.g., 100 W to about 300 W), and the biasing power (e.g., 200 W to about 400 W) used during the passivation step is greater than the etch step 141 (e.g., 100 W to about 300 W). In some embodiments, the treatment step 145 in the first process cycle may be performed in the same process chamber as the passivation step of the first process cycle.

FIG. 10 shows an etch step 147 of a second process cycle in the cyclic process. The etch step 147 is performed to remove the softened passivation layer 143a (FIG. 9) and the first and second semiconductor layers 106, 108, thereby forming the trenches 1802 with a second depth. The trenches 1802 are formed with a straight and symmetric sidewall profile with respect to an imaginary line passing through a center of the trenches 1802 in the depth direction of the trenches 1802. The etch step 147 may be performed using an etch chemistry similar or identical to the etch step 141. The etch step 147 is substantially identical to the etch step 141 except for a higher biasing power is used. In some embodiments, the etch step 147 of the second process cycle uses a biasing power that is greater than that of the treatment step 145 used in the first process cycle.

In one embodiment, the source power (e.g., about 100 W to about 300 W) used during the etch step 147 is substantially the same as that (e.g., about 100 W to about 300 W) of the etch step 141, and the biasing power (e.g., about 200 W to about 500 W) used during the etch step 147 is greater than that (e.g., about 100 W to about 300 W) of the etch step 141. Alternatively, the source power used during the etch step 147 is greater than that of the etch step 141. The chamber pressure used during the etch step 141 and the etch step 147 are substantially the same (e.g., about 5 mTorr to about 20 mTorr). In one exemplary embodiment, the etch step 147 uses a plasma formed from a gas mixture containing CH₄, Cl₂, HBr, CHF₃, for example.

The etch step 147 extends the depth of the trenches 1802. In some embodiments, the etch step 147 is performed until the second highest second semiconductor layer 108 of the stack of semiconductor layers 104 is etched through. After the etch step 147, the trenches 1802 may have a depth D2, which is defined by a distance between the topmost first semiconductor layer 106 and a bottom surface 1802bs2 of the trenches 1802. In other words, the depth of trenches 1802 is extended from depth D1 to depth D2. In some embodiments, the bottom surface 1802bs2 of the trenches 1802 is at or near an interface defined by the second highest second semiconductor layer 108 of the stack of semiconductor layers 104 and the first semiconductor layer 106 disposed immediately below.

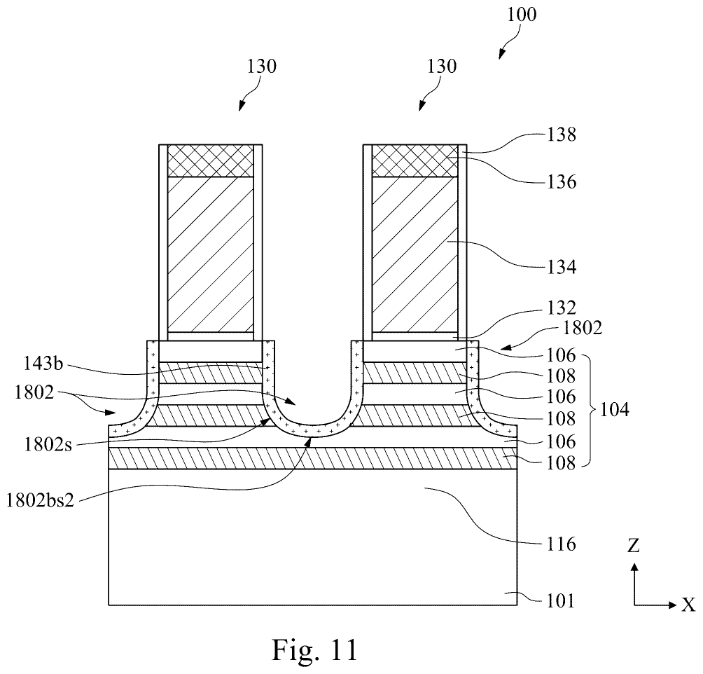

FIG. 11 shows a passivation step of the second process cycle in the cyclic process. The passivation step is performed to form a passivation layer 143b on the exposed surfaces of the trenches 1802, such as a sidewall 1802s and a bottom surface 1802bs2 of the trenches 1802. The passivation layer 143b may be formed from the same material as the passivation layer 143a. Likewise, the passivation layer 143b protects the exposed surfaces of the trenches 1802 from over-etching in the lateral direction during the subsequent etch step. A biasing power is also applied to the substrate support during the passivation step so that the majority of etch chemistries is directed towards the bottom of the trenches 1802. The impact of the etchant on the sidewall 1802s of the trenches 1802 is diminished by the passivation layer 143b. Therefore, the trenches 1802 can be extended vertically with a straight and symmetric sidewall profile during the subsequent etch step. In some embodiments, the passivation layer 143b may have a thickness between about 1 nm and about 3 nm.

The passivation step in the second process cycle is substantially identical to the passivation step in the first process cycle except that a greater biasing power is used. In some embodiments, the biasing power (e.g., about 20 W to about 80 W) used during the passivation step of the second process cycle is greater than that (e.g., 10 W to about 50 W) of the passivation step performed in the first process cycle, and the source power (e.g., about 200 W to about 500 W) used during the passivation step of the second process cycle is substantially the same as that (e.g., about 200 W to about 500 W) of the passivation step performed in the first process cycle. In some embodiments, the passivation step in the second process cycle may be performed in the same process chamber as the etch step 147 of the first process cycle. The process chamber may be operated at a pressure in a range of about 5 mTorr to about 20 mTorr. In one exemplary embodiment, the passivation step in the second process cycle uses a plasma formed from a gas mixture containing N₂ and/or O₂, for example.

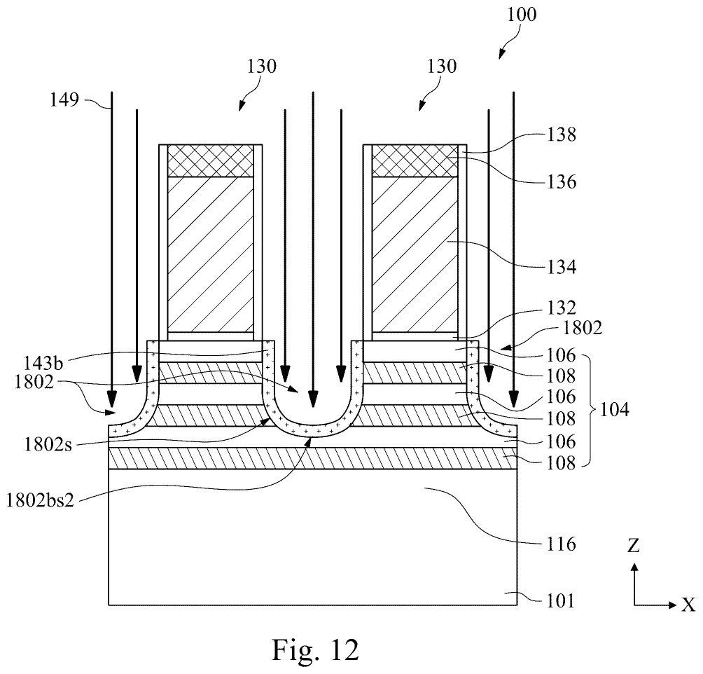

FIG. 12 shows a treatment step 149 of the second process cycle in the cyclic process. The treatment step 149 is performed to bombard and soften the passivation layer 143b, thereby allowing its easy removal during the subsequent etch step at the next process cycle. The treatment step 149 of the second process cycle is substantially identical to the treatment step 145 in the first process cycle except that a greater biasing power is used. In some embodiments, the biasing power (e.g., about 300 W to about 500 W) used during the treatment step 149 of the second process cycle is greater than that (e.g., 200 W to about 400 W) of the treatment step 145 performed in the first process cycle, and the source power (e.g., about 50 W to about 100 W) used during the treatment step 149 of the second process cycle is substantially the same as that (e.g., about 50 W to about 100 W) of the treatment step 145 performed in the first process cycle. In some embodiments, the treatment step 149 in the second process cycle may be performed in the same process chamber as the passivation step of the second process cycle. The process chamber may be operated at a pressure in a range of about 50 mTorr to about 100 mTorr.

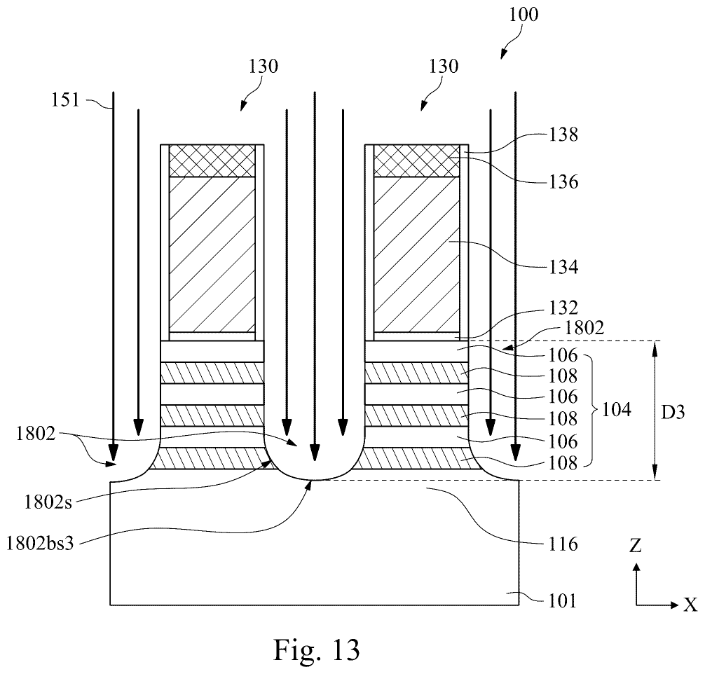

FIG. 13 shows an etch step 151 of a third process cycle in the cyclic process. The etch step 151 is performed to remove the softened passivation layer 143b (FIG. 12) and the first and second semiconductor layers 106, 108, thereby forming a third section of the trenches 1802. The third section of the trenches 1802 is formed with a straight and symmetric sidewall profile with respect to the imaginary line passing through the center of the trenches 1802 in the depth direction of the trenches 1802. The etch step 151 may be performed using an etch chemistry similar or identical to the etch step 147. The etch step 151 is substantially identical to the etch step 147 except for a higher biasing power is used. In some embodiments, the etch step 151 of the third process cycle uses a biasing power that is greater than that of the treatment step 149 used in the second process cycle.

In one embodiment, the source power (e.g., about 100 W to about 300 W) used during the etch step 151 is substantially the same as that (e.g., about 100 W to about 300 W) of the etch step 147 performed in the second process cycle, and the biasing power (e.g., about 300 W to about 600 W) used during the etch step 151 is greater than that (e.g., about 200 W to about 500 W) of the etch step 147 performed in the second process cycle. Alternatively, the source power used during the etch step 151 is greater than that of the etch step 147. The chamber pressure used during the etch step 151 and the etch step 147 are substantially the same (e.g., about 5 mTorr to about 20 mTorr). In one exemplary embodiment, the etch step 151 uses a plasma formed from a gas mixture containing CH₄, Cl₂, HBr, CHF₃, for example.

The etch step 151 is performed to further extend the depth of the trenches 1802. In cases where the fin structure 112 includes three second semiconductor layers 108, the etch step 147 is performed until the third highest second semiconductor layer 108 of the stack of semiconductor layers 104 is etched through. After the etch step 151, the trenches 1802 may have a depth D3, which is defined by a distance between the topmost first semiconductor layer 106 and a bottom surface 1802bs3 of the trenches 1802. In other words, the depth of trenches 1802 is extended from depth D2 to depth D3. In some embodiments, the bottom surface 1802bs3 of the trenches 1802 is at or near an interface defined by the third highest second semiconductor layer 108 of the stack of semiconductor layers 104 and the first semiconductor layer 106 disposed immediately below.

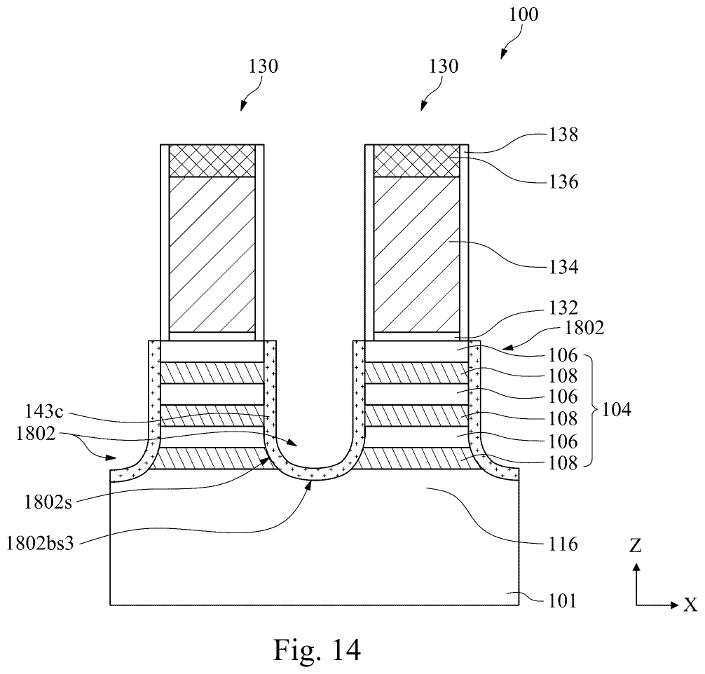

FIG. 14 shows a passivation step of the third process cycle in the cyclic process. The passivation step is performed to form a passivation layer 143c on the exposed surfaces of the trenches 1802, such as a sidewall 1802s and a bottom surface 1802bs3 of the trenches 1802. The passivation layer 143c may be formed from the same material as the passivation layer 143a. Likewise, the passivation layer 143c protects the exposed surfaces of the trenches 1802 from over-etching in the lateral direction during the subsequent etch step. A biasing power is also applied to the substrate support during the passivation step so that the majority of etch chemistries is directed towards the bottom of the trenches 1802. The impact of the etchant on the sidewall 1802s of the trenches 1802 is diminished by the passivation layer 143c. Therefore, the trenches 1802 can be extended vertically with a straight and symmetric sidewall profile during the subsequent etch step. In some embodiments, the passivation layer 143b may have a thickness between about 1 nm and about 3 nm.

The passivation step in the third process cycle is substantially identical to the passivation step in the second process cycle except that a greater biasing power is used. In some embodiments, the biasing power (e.g., about 50 W to about 100 W) used during the passivation step of the third process cycle is greater than that (e.g., 20 W to about 80 W) of the passivation step performed in the second process cycle, and the source power (e.g., about 200 W to about 500 W) used during the passivation step of the second process cycle is substantially the same as that (e.g., about 200 W to about 500 W) of the passivation step performed in the second process cycle. In some embodiments, the passivation step in the third process cycle may be performed in the same process chamber as the etch step 151 of the second process cycle. The process chamber may be operated at a pressure in a range of about 5 mTorr to about 20 mTorr. In one exemplary embodiment, the passivation step in the third process cycle uses a plasma formed from a gas mixture containing N₂ and/or O₂, for example.

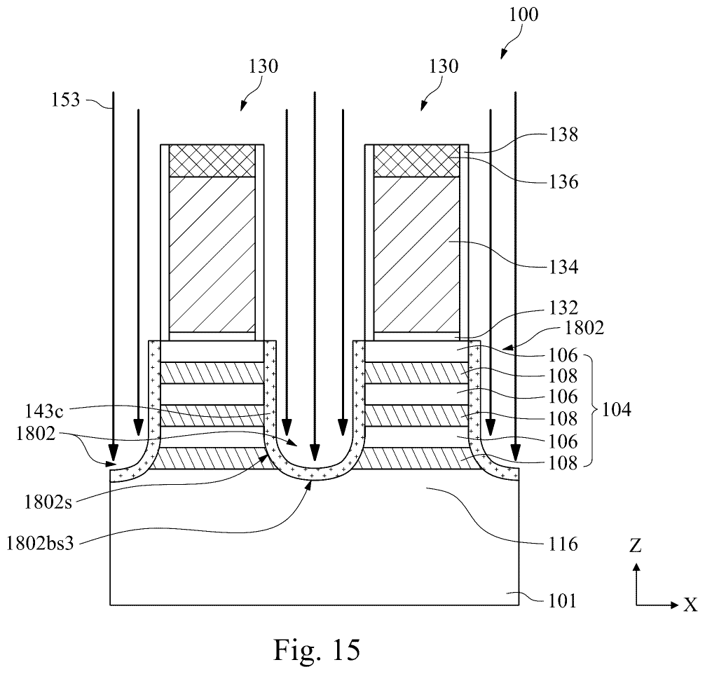

FIG. 15 shows a treatment step 153 of the third process cycle in the cyclic process. The treatment step 153 is performed to bombard and soften the passivation layer 143c, thereby allowing its easy removal during the subsequent etch step at the next process cycle. The treatment step 153 of the third process cycle is substantially identical to the treatment step 149 in the second process cycle except that a greater biasing power is used. In some embodiments, the biasing power (e.g., about 500 W to about 1000 W) used during the treatment step 153 of the third process cycle is greater than that (e.g., 300 W to about 500 W) of the treatment step 149 performed in the second process cycle, and the source power (e.g., about 50 W to about 100 W) used during the treatment step 153 of the third process cycle is substantially the same as that (e.g., about 50 W to about 100 W) of the treatment step 149 performed in the second process cycle. In some embodiments, the treatment step 153 in the third process cycle may be performed in the same process chamber as the passivation step of the third process cycle. The process chamber may be operated at a pressure in a range of about 50 mTorr to about 100 mTorr.

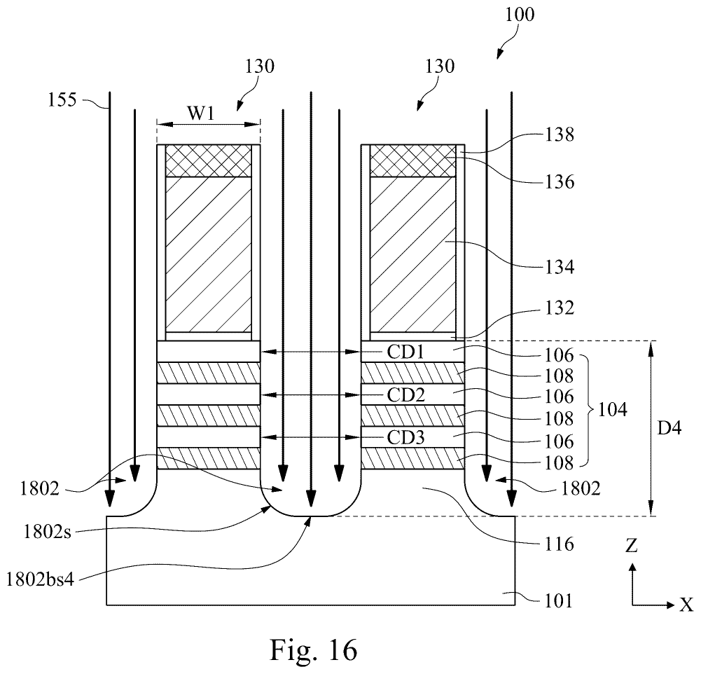

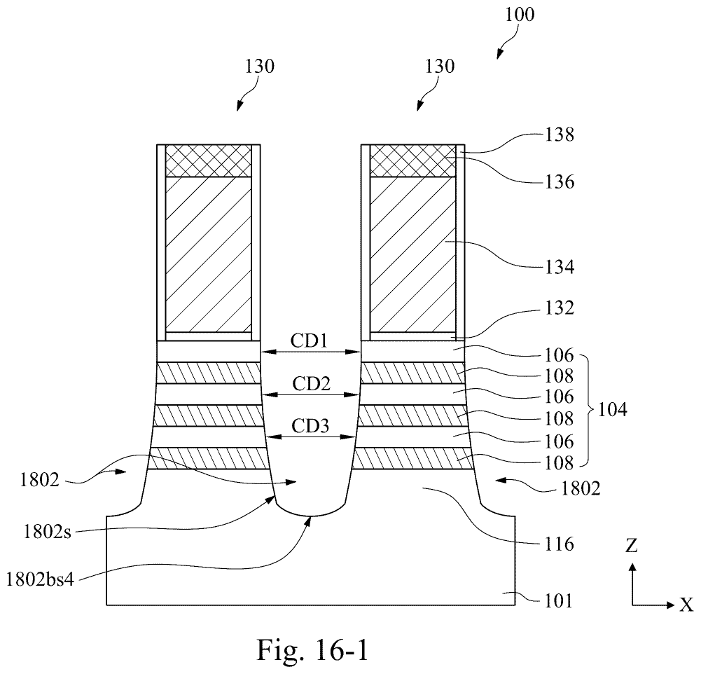

FIG. 16 shows the semiconductor device structure 100 is subjected to an etch step 155. The etch step 155 is performed to remove the softened passivation layer 143c (FIG. 15) and a portion of the substrate 101, thereby forming a fourth section of the trenches 1802. The fourth section of the trenches 1802 is formed with a straight and symmetric sidewall profile with respect to the imaginary line passing through the center of the trenches 1802 in the depth direction of the trenches 1802. In some embodiments, the fourth section of the trenches 1802 is formed with a curved profile at the bottom. In some embodiments, the fourth section of the trenches 1802 is formed with a substantially flat profile at the bottom. In some embodiments, the fourth section of the trenches 1802 is formed with a tapering profile at the bottom.

The etch step 155 may be performed using an etch chemistry similar or identical to the etch step 151. The etch step 155 is substantially identical to the etch step 151 except for a higher biasing power is used. In some embodiments, the etch step 155 uses a biasing power that is greater than that of the treatment step 153 used in the third process cycle.

In one embodiment, the source power (e.g., about 100 W to about 300 W) used during the etch step 155 is substantially the same as that (e.g., about 100 W to about 300 W) of the etch step 151 performed in the third process cycle, and the biasing power (e.g., about 400 W to about 700 W) used during the etch step 155 is greater than that (e.g., about 300 W to about 600 W) of the etch step 151 performed in the third process cycle. The chamber pressure used during the etch step 155 and the etch step 151 are substantially the same (e.g., about 5 mTorr to about 20 mTorr). In one exemplary embodiment, the etch step 155 uses a plasma formed from a gas mixture containing CH₄, Cl₂, HBr, CHF₃, for example.

The etch step 155 further extends the depth of the trenches 1802. The etch step 155 may be performed until the trenches 1802 reaches a pre-determined depth below an interface defined by the bottommost second semiconductor layers 108 and the substrate 101. After the etch step 155, the trenches 1802 may have a depth D4, which is defined by a distance between the topmost first semiconductor layer 106 and a bottom surface 1802bs4 of the trenches 1802. In other words, the depth of trenches 1802 is extended from depth D3 to depth D4. In some embodiments, the bottom surface 1802bs4 of the trenches 1802 is about 5 nm to about 10 nm below the interface defined by the bottommost second semiconductor layers 108 and the substrate 101.

The processes described in FIGS. 7-16 may repeat two or more times until a desired depth of the trenches 1802 is reached. In some embodiments, the total number of the process cycle may correspond to the number of the second semiconductor layers 108 in the fin structure 112. In any case, the trenches 1802 as formed have a straight vertical sidewall profile with a substantially uniform critical dimension (CD) from top to bottom. In some embodiments, the first section of the trenches 1802 at or near the topmost first semiconductor layer 106 has a first CD (CD1), the second section of the trenches 1802 at or near the second highest first semiconductor layer 106 of the stack of semiconductor layers 104 has a second CD (CD2), and the third section of the trenches 1802 at or near the third highest first semiconductor layer 106 of the stack of semiconductor layers 104 has a third CD (CD3). In some embodiments, the CD1, the CD2, and the CD3 are substantially the same. Each of the first semiconductor layers 106 in the fin structure 112 may have a width W1 that is substantially identical to one another. In some embodiments where the gate pitch is about 40 nm to about 50 nm, the CD3 may be about 0 nm to about 1 nm greater than the width W1.

In some embodiments, the CD1 and the CD2 are substantially the same, and the CD3 is slightly less than the CD1 and the CD2, such as an embodiment shown in FIG. 16-1. In such cases, the difference between the CD1 (or the CD2) and the CD3 is less than 2 nm, for example about 0 nm to about 1 nm, such as about 0.5 nm, and the dimension of the first semiconductor layers 106 is gradually increased along the direction away from the sacrificial gate dielectric layer 132.

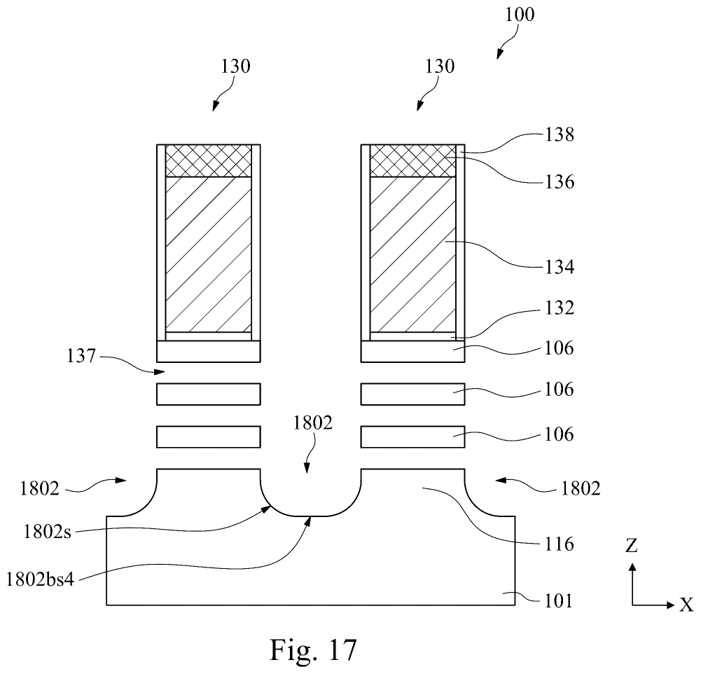

In FIG. 17, the second semiconductor layers 108 are removed. The removal of the second semiconductor layers 108 forms openings 137. The second semiconductor layers 108 may be removed by a selective etch process, such as a selective dry etch process, a selective wet etch process, or a combination thereof. The selective etch process does not substantially affect the gate spacers 138, the first semiconductor layers 106, the sacrificial gate electrode layers 130, and the substrate 101. In some embodiments, the selective etch process is a selective wet etching process. In cases where the second semiconductor layers 108 are made of SiGe and the first semiconductor layers 106 are made of silicon, the second semiconductor layer 108 can be selectively etched using an etchant such as, but not limited to, ammonium hydroxide (NH₄OH), tetramethylammonium hydroxide (TMAH), ethylenediamine pyrocatechol (EDP), or potassium hydroxide (KOH) solutions.

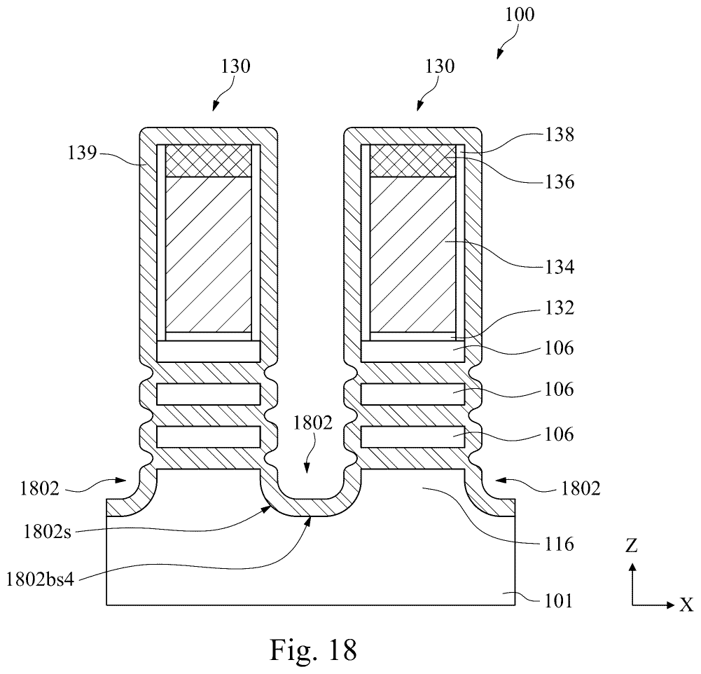

In FIG. 18, a sacrificial dielectric material 139 is formed in the openings 137 and on the exposed surfaces of the semiconductor device structure 100. In some embodiments, the sacrificial dielectric material 139 is an oxide formed by flowable chemical vapor deposition (FCVD) process. In some embodiments, the oxide is a carbon-containing silicon oxide. The use of the sacrificial dielectric material 139 helps to preserve surface profile of the first semiconductor layers 106 during the subsequent sheet (or channel) formation stage. In traditional cases where the second semiconductor layers 108 include Ge and the first semiconductor layers 106 include silicon, the Ge in the second semiconductor layers 108 may diffuse into and react with Si to form SiGe due to high temperature used during the formation of the subsequent epitaxial S/D features 146. When the second semiconductor layers 108 are selectively removed during the sheet formation stage, a surface portion of the first semiconductor layers 106, which is now SiGe due to prior reaction with Ge, will also be removed. The removal of the second semiconductor layers 108 therefore induces extra silicon loss (e.g., about 1.5 to 2.5 nm in thickness) in the surface portion of the first semiconductor layers 106, resulting in thickness reduction and/or concave-like damage to the first semiconductor layers 106. When the thickness of silicon nanosheet channel layers (i.e., first semiconductor layers 106) is affected, the channel resistance (Rch) of the nanosheet channel layers may increase and the ability of the nanosheet channel layers to conduct current flow (e.g., DC) may be reduced. By replacing the second semiconductor layers 108 with a sacrificial dielectric layer 139 prior to formation of epitaxial S/D features 146, there is minimum reaction between the first semiconductor layers 106 and the sacrificial dielectric layer 139 during the subsequent formation of the epitaxial S/D features 146, and the sacrificial dielectric layer 139 can be removed with an enhanced etch selectivity over the first semiconductor layers 106. Since the surface profile of the first semiconductor layers 106 remains substantially intact during the sheet formation stage, the channel resistance of the nanosheet channel layers is not increased and the issues discussed herein are avoided.

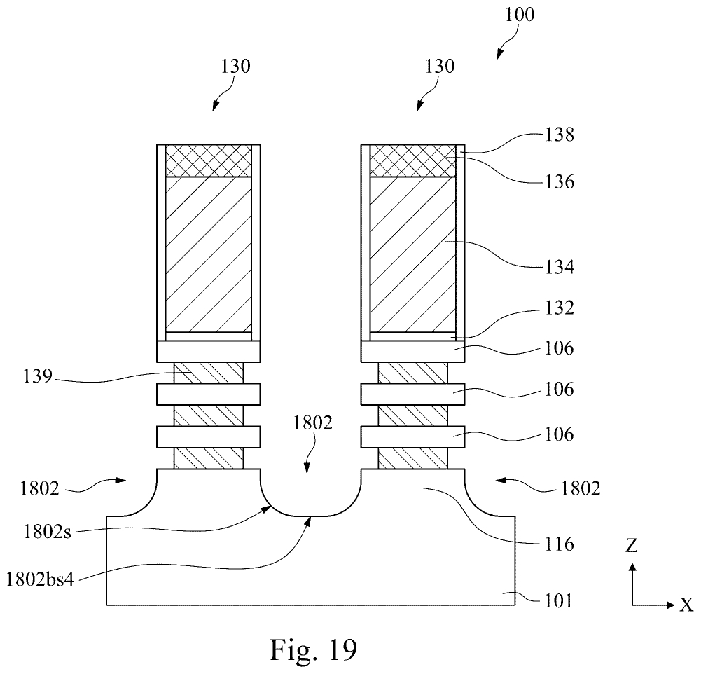

In FIG. 19, an etch back process is performed to remove portions of the sacrificial dielectric layers 139 other than the portions of the sacrificial dielectric layers 139 formed in the openings 137 (FIG. 17). In some embodiments, the etch back process is an anisotropic etching process. The etch back process may be a selective etch process that removes the sacrificial dielectric layers 139 but does not substantially affect the sacrificial gate structures 130, the gate spacers 138, the first semiconductor layers 106, and the substrate 101. The selective etch process is performed until edge portions of each sacrificial dielectric layer 139 between first semiconductor layers 106 are removed. Therefore, the majority of the sacrificial dielectric layers 139 between the first semiconductor layers 106 remains after the etch back process.

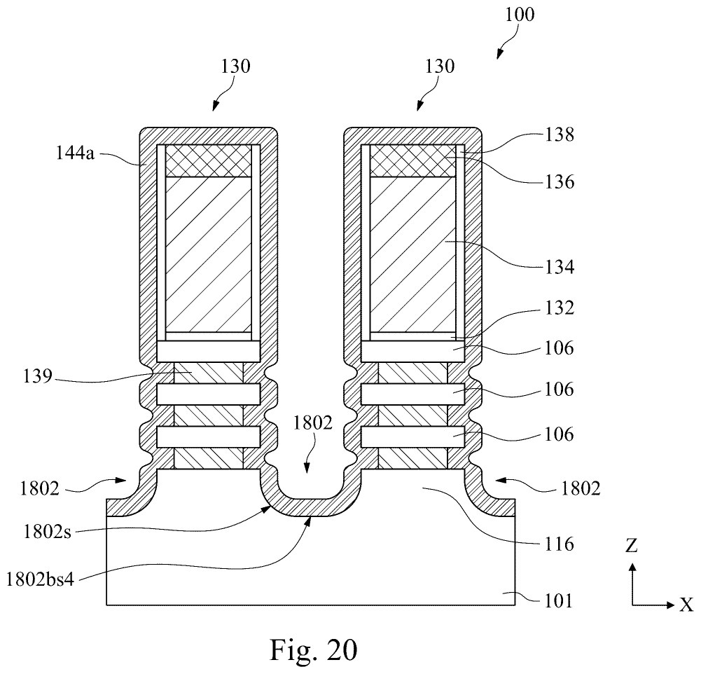

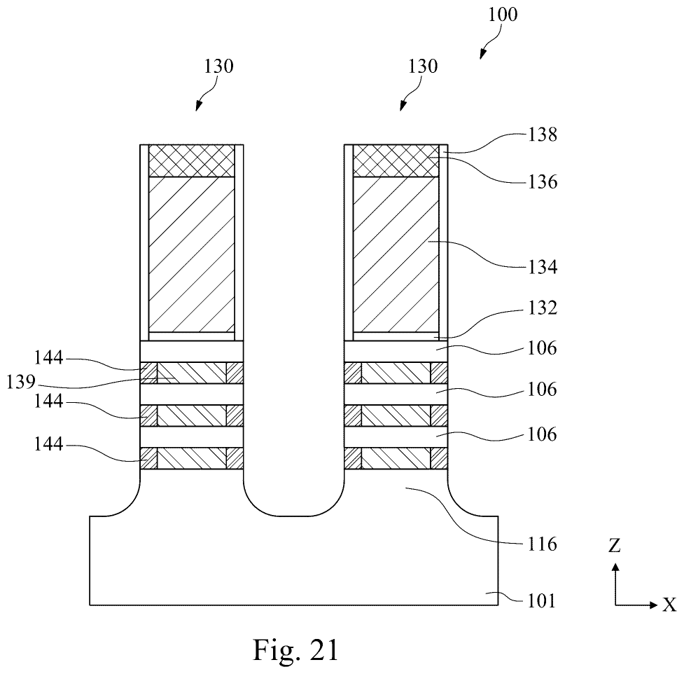

In FIG. 20, after removing edge portions of the sacrificial dielectric material 139, a dielectric layer 144a is deposited in the cavities formed as a result of removal of the edge portions of the sacrificial dielectric layer 139. The dielectric layer 144a in the cavities forms dielectric spacers 144, as shown in FIG. 21. The dielectric layer 144a may be made of a dielectric material, such as SiO₂, Si3N4, SiC, SiCP, SION, SiOC, SiCN, SiOCN, and/or other suitable material. The dielectric layer 144a may be deposited as a conformal dielectric layer using a conformal deposition process, such as ALD.

In FIG. 21, an anisotropic etching is performed to remove portions of the conformal dielectric layer 144a other than the dielectric layer 144a formed in the cavities. The dielectric layer 144a in the cavities forms dielectric spacers 144, and are protected by the first semiconductor layers 106 during the anisotropic etching process. The sacrificial dielectric layer 139 is capped between the dielectric spacers 144 along the X direction. In some embodiments, the dielectric spacers 144 and the sacrificial dielectric material 139 include different materials having different etch selectivity.

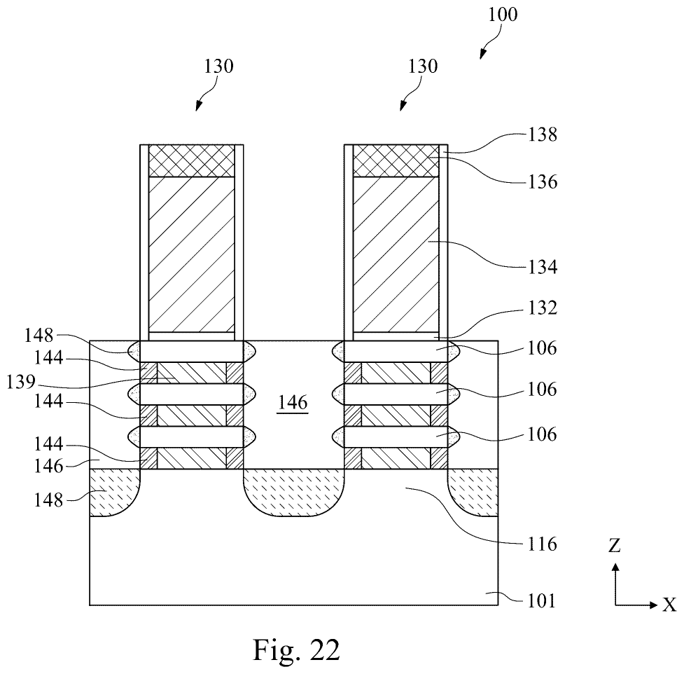

In FIG. 22, epitaxial S/D features 146 are formed in the source/drain (S/D) regions. The epitaxial S/D features 146 may grow vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures. In any case, the epitaxial S/D features 146 are formed with a substantially uniform CD from top to bottom. For example, the epitaxial S/D features 146 may have a dimension corresponding to CD1, CD2, and CD3 shown in FIG. 16. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 are in contact with the first semiconductor layers 106 and the inner spacers 144. The second semiconductor layers 108 under the sacrificial gate structure 130 are separated from the epitaxial S/D features 146 by the dielectric spacers 144.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

In some embodiments, after formation of the dielectric spacers 144, a facetted structure 148 is formed on exposed surfaces of the first semiconductor layers 106 and exposed surfaces (e.g., well portion 116) of the substrate 101 to promote epitaxial growth of subsequent S/D features 146. In some embodiments, a portion of the facetted structure 148 may be in further contact with the dielectric spacer 144. The facetted structures 148 may grow both vertically and horizontally to form facets, which may correspond to crystal planes of the material of the first semiconductor layers 106 and exposed surfaces of the substrate 101. Due to different growth rates on different surface planes, facets can be formed. For example, during the growth of the facetted structures 148, the growth rate on (111) planes of the first semiconductor layer 106 (e.g., silicon) may be lower than the growth rate on other planes, such as (110) and (100) planes of the first semiconductor layer 106. Therefore, facets are formed as a result of difference in growth rates of the different planes. In one embodiment, the facetted structures 148 have a rhombus-like shape. Comparing to the exposed surfaces of the first semiconductor layer 106, the facets of the facetted structures 148 provide increased surface area to promote epitaxial growth of the S/D features 146. Once the facetted structures 148 are formed, the S/D features 146 may grow on the facetted structures 148 and cover the exposed surfaces of the facetted structures 148.

In some embodiments, the facetted structures 148 include silicon. In some embodiments, the facetted structures 148 include silicon and n-type or p-type dopants, depending on the conductivity type of the S/D features 146 to be grown thereon. For example, the facetted structure 148 at a n-type device region may be silicon doped with n-type dopants, such as phosphorous or arsenic, and the facetted structure 148 at a p-type device region may be silicon doped with p-type dopants, such as boron. The facet structures 148 may be formed using selective epitaxial growth (SEG), ALD, MBE, or any suitable growth process. In some embodiments, the first semiconductor layers 106 may be exposed to silicon-containing precursor(s) and n-type or p-type dopant-containing precursor(s) in a process chamber to form facetted structure 148. The process conditions of the growth process are configured in accordance with the crystal planes of the first semiconductor layer 106 and the substrate 101 to promote faceting formation of the facetted structures 148. Once the predetermined volume of the facetted structures 148 is reached, the flow of the n-type or p-type dopant-containing precursor(s) may be terminated and group IV or group V precursor(s) are introduced into the process chamber along with the silicon-containing precursor(S) to form the S/D features 146. Therefore, the facetted structures 148 are formed of a material that is chemically different from that of the S/D features 146. The dopants in the S/D features 146 may be added during the formation of the S/D features 146, or after the formation of the S/D features 146 by an implantation process.

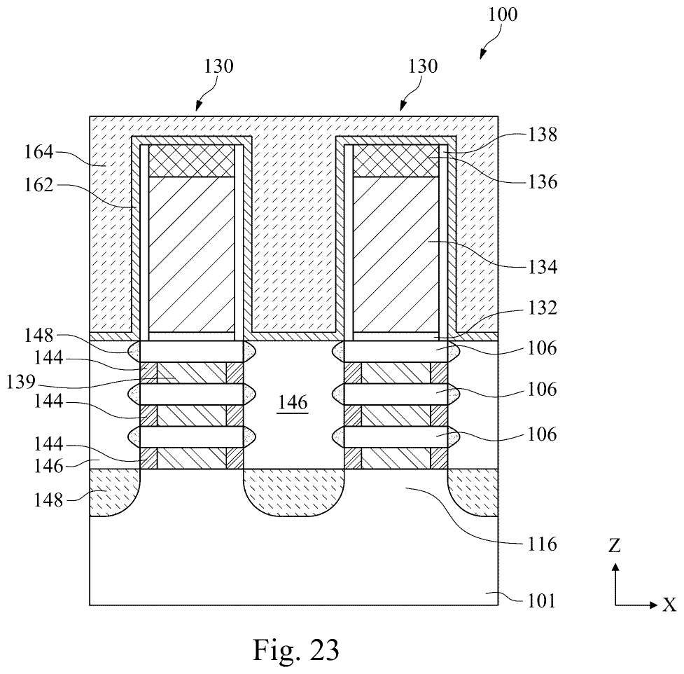

In FIG. 23, a contact etch stop layer (CESL) 162 is conformally formed on the exposed surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, and may be formed by CVD, PECVD, ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164.

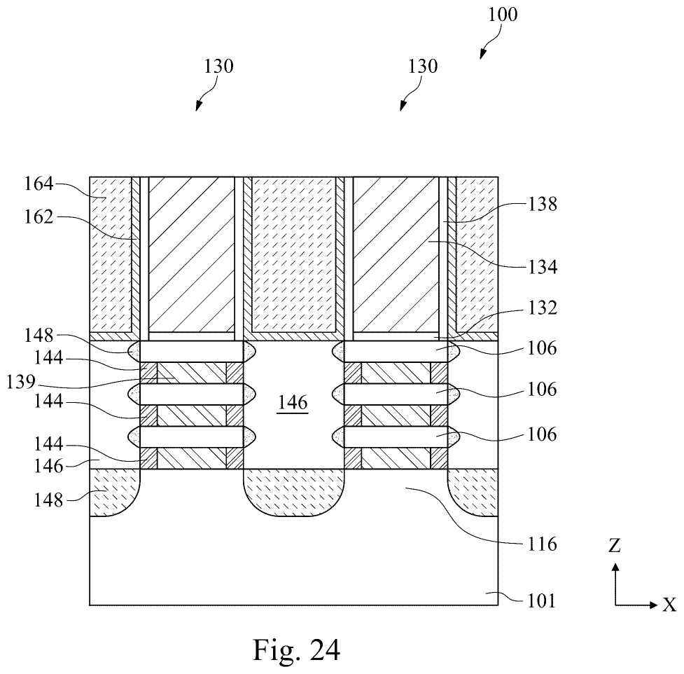

In FIG. 24, after the first ILD layer 164 is formed, a planarization operation, such as CMP, is performed on the semiconductor device structure 100 until the sacrificial gate electrode layer 134 is exposed. The top surfaces of the sacrificial gate electrode layer 134, the gate spacers 138, the CESL 162, and the first ILD layer 164 are substantially co-planar after the CMP.

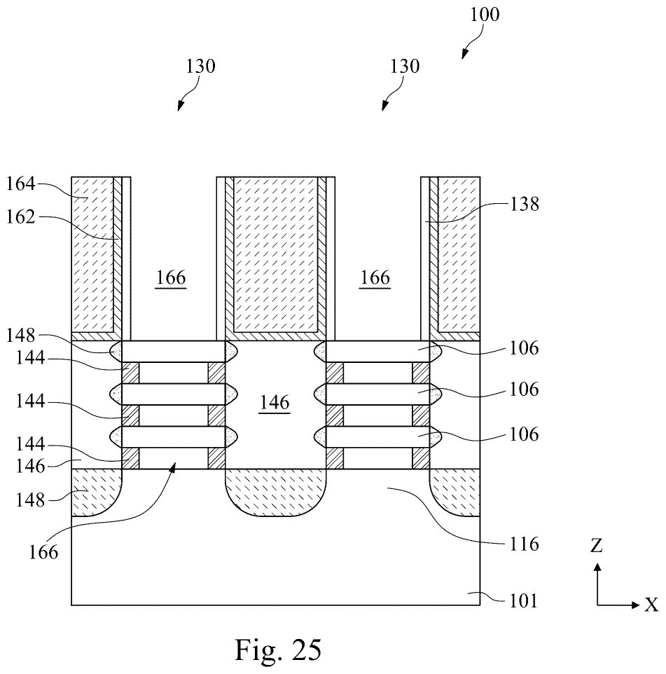

In FIG. 25, the sacrificial gate structures 130, the sacrificial gate dielectric layer 132, and the sacrificial dielectric layers 139 are removed (i.e., sheet formation stage). The removal of the sacrificial gate structures 130 and the sacrificial dielectric layers 139 forms an opening 166 between the first semiconductor layers 106. The sacrificial gate structures 130 can be removed using plasma dry etching and/or wet etching. In some embodiments, a wet etchant such as a tetramethylammonium hydroxide (TMAH) solution can be used to selectively remove the sacrificial dielectric layers 139, the sacrificial gate electrode layer 134, and the sacrificial gate dielectric layer 132 but not the gate spacers 138, the first ILD layer 164, and the CESL 162. After the removal of the sacrificial gate structures 130, the first semiconductor layers 106 and the inner spacers 144 are exposed to the opening 166.

The sacrificial dielectric layers 139 disposed between the first semiconductor layers 106 help preserve the integrity and surface profile of the first semiconductor layers 106 during the sheet formation stage since the sacrificial dielectric layers 139 do not react or intermix with the first semiconductor layers 106 in prior high temperature process of the epitaxial S/D features 146. Therefore, the sacrificial dielectric layers 139 can be removed without damaging the first semiconductor layers 106 during the sheet formation stage.

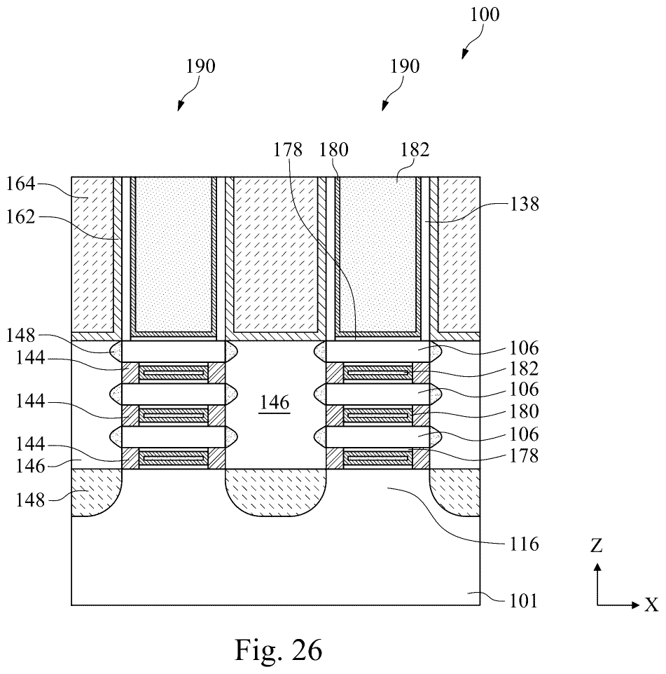

In FIG. 26, replacement gate structures 190 are formed. The replacement gate structures 190 may each include a gate dielectric layer 180 and a gate electrode layer 182. In some embodiments, an interfacial layer (IL) 178 may be formed between the gate dielectric layer 180 and the first semiconductor layer 106. The IL 178 may also form on the exposed surfaces of the substrate 101. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, and the CESL 162). The gate dielectric layer 180 may be formed of a material chemically different than that of the sacrificial gate dielectric layer 132. The gate dielectric layer 180 may include or made of a high-k dielectric material. The gate dielectric layer 180 may be a conformal layer formed by a conformal process, such as an ALD process, a PECVD process, a molecular-beam deposition (MBD) process, or the like, or a combination thereof.

After formation of the IL 178 and the gate dielectric layer 180, the gate electrode layer 182 is formed on the gate dielectric layer 180. The gate electrode layer 182 filles the openings 166 (FIG. 25) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, and the gate spacers 138 may be removed by a planarization process, such as by a CMP process. After the CMP process, the top surfaces of the first ILD layer 164, the CESL 162, the gate spacers 138, gate dielectric layer 180, and the gate electrode layer 182 are substantially co-planar.

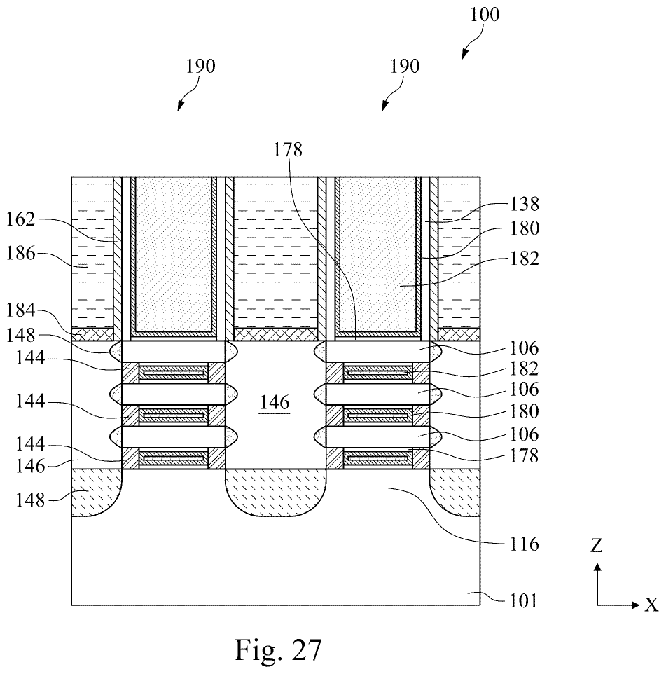

In FIG. 27, contact openings are formed through the first ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. While not shown, a barrier layer (e.g., TiN, TaN, or the like) may be formed on sidewalls of the contact openings prior to forming the S/D contacts 186. The silicide layer 184 conductively couples the epitaxial S/D features 146 to subsequent S/D contacts 186 formed in the contact openings. The silicide layer 184 may include a metal or metal alloy silicide, and the metal includes a noble metal, a refractory metal, a rare earth metal, alloys thereof, or combinations thereof. Then, a planarization process, such as CMP, is performed to remove excess deposition of the contact material and expose the top surface of the gate electrode layer 182.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Embodiments of the present disclosure provide improved sheet formation process and etch profile control for forming source/drain trenches. The etch profile control is achieved by a cyclic process including an etch step, a passivation step, and a treatment step which allows the source/drain trenches to be formed with a straight vertical sidewall profile without a bowing profile. Prior to forming epitaxial S/D features, SiGe layers between Si nanosheet channel layers are replaced with sacrificial dielectric layers. The sacrificial dielectric layers have minimum reaction with the nanosheet channel layers during subsequent high temperature process of epitaxial S/D features and can be easily removed during sheet formation process. Since the integrity and surface profile of the nanosheet channel layers are preserved during the sheet formation process, a channel resistance between a source feature and a drain feature can be reduced. As a result, the device performance is improved.

An embodiment is a method for forming a semiconductor device structure. The method includes forming a trench between two adjacent fin structures each comprising a plurality of first semiconductor layers and a plurality of second semiconductor layers alternatingly stacked, removing the second semiconductor layers in each fin structure to form first cavities, filling the first cavities with a sacrificial dielectric layer, removing edge portions of each sacrificial dielectric layer to form second cavities, filling the second cavities with a dielectric spacer, forming epitaxial source/drain features in the trench, removing the sacrificial dielectric layers, and surrounding a portion of each first semiconductor layer with a gate electrode layer.

Another embodiment is a method for forming a semiconductor device structure. The method includes removing, using a first etchant, a portion of a fin structure at a source/drain region to form a trench with a first depth, the fin structure comprising a plurality of first semiconductor layers and a plurality of second semiconductor layers alternatingly stacked. The method also includes passivating exposed surfaces of the trench to modify an etch selectivity of the exposed surfaces to a second etchant, subjecting the passivated surfaces to a treatment process, removing, using the second etchant, the passivated surface and a portion of the fin structure to form the trench with a second depth that is greater than the first depth. The method further includes replacing the second semiconductor layers in the fin structure with a sacrificial dielectric layer, forming epitaxial source/drain features in the trench, removing the sacrificial dielectric layers, and surrounding a portion of each first semiconductor layer with a gate electrode layer.

A further embodiment is a method for forming a semiconductor device structure. The method includes (1) forming a fin structure comprising a plurality of a first semiconductor layers and a plurality of a second semiconductor layers alternatingly stacked, (2) performing a first etch process to form a trench with a first depth at a source/drain region of the fin structure, the first etch process using a first biasing power, (3) passivating exposed surfaces of the trench using a second biasing power different than the first biasing power, (4) treating the passivated exposed surfaces using a third biasing power different than the first biasing power, (5) performing a second etch process using a fourth biasing power to extend the trench from the first depth to a second depth, the fourth biasing power being different than the third biasing power, (6) replacing the second semiconductor layers in the fin structure with a sacrificial dielectric layer, (7) forming epitaxial source/drain features in the trench, (8) removing the sacrificial dielectric layers, and (9) surrounding a portion of each first semiconductor layer with a gate electrode layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a trench between two adjacent fin structures each comprising a plurality of first semiconductor layers and a plurality of second semiconductor layers alternatingly stacked;
removing the second semiconductor layers in each fin structure to form first cavities;
filling the first cavities with a sacrificial dielectric layer;
removing edge portions of each sacrificial dielectric layer to form second cavities;
filling the second cavities with a dielectric spacer;
forming epitaxial source/drain features in the trench;
removing the sacrificial dielectric layers; and
surrounding a portion of each first semiconductor layer with a gate electrode layer.

2. The method of claim 1, wherein the sacrificial dielectric layer is made of an oxide.

3. The method of claim 1, wherein each of the sacrificial dielectric layer and the dielectric spacer includes a material chemically different from each other.

4. The method of claim 1, wherein an upper portion of the trench has a first diameter and a lower portion of the trench has a second diameter that is substantially identical to the first diameter.

5. The method of claim 1, wherein an upper portion of the trench has a first diameter and a lower portion of the trench has a second diameter that is smaller than the first diameter.

6. The method of claim 1, further comprising:
prior to forming epitaxial source/drain features, growing a facetted structure on a sidewall of each first semiconductor layer.

7. The method of claim 6, wherein the facetted structure is formed of a material that is chemically different from that of the epitaxial source/drain features.

8. A method for forming a semiconductor device structure, comprising:
removing, using a first etchant, a portion of a fin structure at a source/drain region to form a trench with a first depth, the fin structure comprising a plurality of first semiconductor layers and a plurality of second semiconductor layers alternatingly stacked;
passivating exposed surfaces of the trench to modify an etch selectivity of the exposed surfaces to a second etchant;
subjecting the passivated surfaces to a treatment process;
removing, using the second etchant, the passivated surface and a portion of the fin structure to form the trench with a second depth that is greater than the first depth;
replacing the second semiconductor layers in the fin structure with a sacrificial dielectric layer;
forming epitaxial source/drain features in the trench;
removing the sacrificial dielectric layers; and
surrounding a portion of each first semiconductor layer with a gate electrode layer.

9. The method of claim 8, wherein the sacrificial dielectric layer is made of an oxide.

10. The method of claim 8 wherein the etch selectivity of the exposed surfaces is modified by forming a passivation layer on the exposed surfaces of a first section of the trench.

11. The method of claim 10, wherein the passivation layer is formed by exposing the exposed surfaces of the first section of the trench to a gas mixture comprising an oxygen-containing precursor or a nitrogen-containing precursor.

12. The method of claim 8, wherein the treatment process is performed by bombarding the passivation layer with neutral radical of species formed from a nitrogen-containing gas and/or a hydrogen-containing gas.

13. The method of claim 8, wherein the trench is formed with a straight vertical sidewall profile.

14. The method of claim 8, wherein the first etchant and the second etchant are substantially the same.

15. The method of claim 14, wherein the first and second etchants comprise a hydrocarbon-based etch chemistry, a bromine-based etch chemistry, a chlorine-based etch chemistry, and/or a fluorine-based etch chemistry.

16. A method for forming a semiconductor device structure, comprising:
(1) forming a fin structure comprising a plurality of a first semiconductor layers and a plurality of a second semiconductor layers alternatingly stacked;
(2) performing a first etch process to form a trench with a first depth at a source/drain region of the fin structure, the first etch process using a first biasing power;
(3) passivating exposed surfaces of the trench using a second biasing power different than the first biasing power;
(4) treating the passivated exposed surfaces using a third biasing power different than the first biasing power;
(5) performing a second etch process using a fourth biasing power to extend the trench from the first depth to a second depth, the fourth biasing power being different than the third biasing power;
(6) replacing the second semiconductor layers in the fin structure with a sacrificial dielectric layer;
(7) forming epitaxial source/drain features in the trench;
(8) removing the sacrificial dielectric layers; and
(9) surrounding a portion of each first semiconductor layer with a gate electrode layer.

17. The method of claim 16, further comprising:
after operation (5), repeating operations (2) to (5) as a cyclic process until the trench reaches a pre-determined depth.

18. The method of claim 17, wherein the first biasing power in a second process cycle of the cyclic process is greater than the first biasing power in a first process cycle of the cyclic process.

19. The method of claim 17, wherein treating the passivated exposed surfaces comprises bombarding the passivated exposed surfaces with neutral radical of species formed from a nitrogen-containing gas and/or a hydrogen-containing gas.

20. The method of claim 17, wherein the sacrificial dielectric layer is made of an oxide.
